(19) United States
(12) Patent Application Publication
(10) Pub. No.: US 2025/0378884 A1
(43) Pub. Date: Dec. 11, 2025

(54) TECHNIQUES FOR NON-VOLATILE MEMORY INITIALIZATION

(71) Applicant: Micron Technology, Inc., Boise, ID (US)

(72) Inventors: Liang Yu, Boise, ID (US); Jonathan S. Parry, Boise, ID (US)

(21) Appl. No.: 19/221,985

(22) Filed: May 29, 2025

Related U.S. Application Data
(60) Provisional application No. 63/658,706, filed on Jun. 11, 2024.

(51) Int. Cl. G11C 16/20; G11C 16/30; G11C 16/32

(52) U.S. Cl. CPC G11C 16/20; G11C 16/30; G11C 16/32

(57) ABSTRACT

Methods, systems, and devices for techniques for non-volatile initialization, such as not-and (NAND) initialization, are described. One or more dies of a memory system may perform an automatically-triggered initialization procedure prior to one or more controllers of the memory system completing a wakeup procedure. For example, the memory system may transition from an idle state to an awake. Accordingly, the one or more dies may perform an initialization procedure in response to a first voltage source, a second voltage source, or both, satisfying respective thresholds, such as by reaching a ready state. After, or in conjunction with, the initialization procedure, the one or more controllers may perform the wakeup procedure in response to the transition of the memory system from the idle state to the awake state, such that the wakeup procedure is performed after a start of, or simultaneously with, the initialization procedure at the one or more dies.

### CROSS REFERENCE

The present Application for Patent claims priority to U.S. Patent Application No. 63/658,706 by Yu et al., entitled “TECHNIQUES FOR NON-VOLATILE MEMORY INITIALIZATION,” filed Jun. 11, 2024, which is assigned to the assignee hereof, and which is expressly incorporated by reference in its entirety herein.

### TECHNICAL FIELD

The following relates to one or more systems for memory, including techniques for non-volatile memory, such as not-and (NAND) memory, initialization.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports techniques non-volatile memory, such as not-and (NAND) memory, initialization in accordance with examples as disclosed herein.

FIG. 2 shows an example of a timing diagram that supports techniques for non-volatile memory, such as NAND memory, initialization in accordance with examples as disclosed herein.

FIG. 3 shows an example of a memory device architecture that supports techniques for non-volatile memory, such as NAND memory, initialization in accordance with examples as disclosed herein.

FIG. 4 shows an example of a memory device architecture that supports techniques for non-volatile memory, such as NAND memory, initialization in accordance with examples as disclosed herein.

FIG. 5 shows a block diagram of a memory system that supports techniques for non-volatile memory, such as NAND memory, initialization in accordance with examples as disclosed herein.

FIG. 6 shows a flowchart illustrating a method or methods that support techniques for non-volatile memory, such as NAND memory, initialization in accordance with examples as disclosed herein.

### DETAILED DESCRIPTION

A memory system may perform one or more initialization procedures (e.g., after power up, after exiting a sleep state) at one or more dies, such as not-and (NAND) dies, to prepare the dies for use by one or more controllers of the memory system. For example, in response to or based on one or more voltage sources satisfying a threshold (e.g., voltage sources reaching a ready state) the one or more controllers may perform a wakeup procedure (e.g., an application-specific integrated circuit (ASIC) wakeup procedure). In such examples, in response to or based on performing the wakeup procedure, the one or more controllers may transmit a respective command to each of the one or more dies to trigger the one or more dies to perform the initialization procedure. However, such serialized performance of the wakeup procedure and the initialization procedure (e.g., the wakeup procedure at the controllers is completed prior to the start of the initialization procedure at the dies) may cause an increase in startup delays at the memory system. Such startup delays may in turn occur each time the memory system exits the sleep state, thus increasing performance delays and latency of the memory system, among other challenges. As such, solutions which reduce startup delays in memory systems are desirable.

The techniques, methods, or devices described herein may enable the one or more dies, such as one or more NAND dies, of the memory system to perform an automatic (e.g., automatically-triggered) initialization procedure prior to the one or more controllers completing a wakeup procedure, thereby reducing latency associated with startup, among other benefits. For example, the memory system may transition from an idle state (e.g., a sleep state) to an awake state according to a first voltage source (e.g., Vcc), a second voltage source (e.g., Vccq), or both, ramping up (e.g., powering on, increasing). The one or more dies may perform an initialization procedure in response to or based on a voltage level of the first voltage source satisfying a first threshold (e.g., Vcc reaching a ready state), in response to or based on a voltage level of the second voltage source satisfying a second threshold (e.g., Vccq reaching a ready state), or both. After, or in conjunction with, the initialization procedure, the one or more controllers may perform a wakeup procedure. In some examples, the one or more controllers may perform the wakeup procedure after a start of the initialization procedure at the one or more dies. In some other cases, the one or more controllers may perform the wakeup procedure and the one or more dies may perform the initialization procedure during a duration that at least partially overlaps (e.g., concurrently, simultaneously). In this way, the one or more dies, such as NAND dies, may perform the initialization procedure before an end of the wakeup procedure at the one or more controllers, thereby reducing startup delays at the memory system.

In addition to applicability in memory systems as described herein, techniques for initialization may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing memory initialization times, which may decrease latency times each time a memory device exits an idle state, improve response times, or otherwise improve user experience, among other benefits.

Features of the disclosure are illustrated and described in the context of systems, devices, and circuits. Features of the disclosure are further illustrated and described in the context of a timing diagram, architectures, and flowcharts.

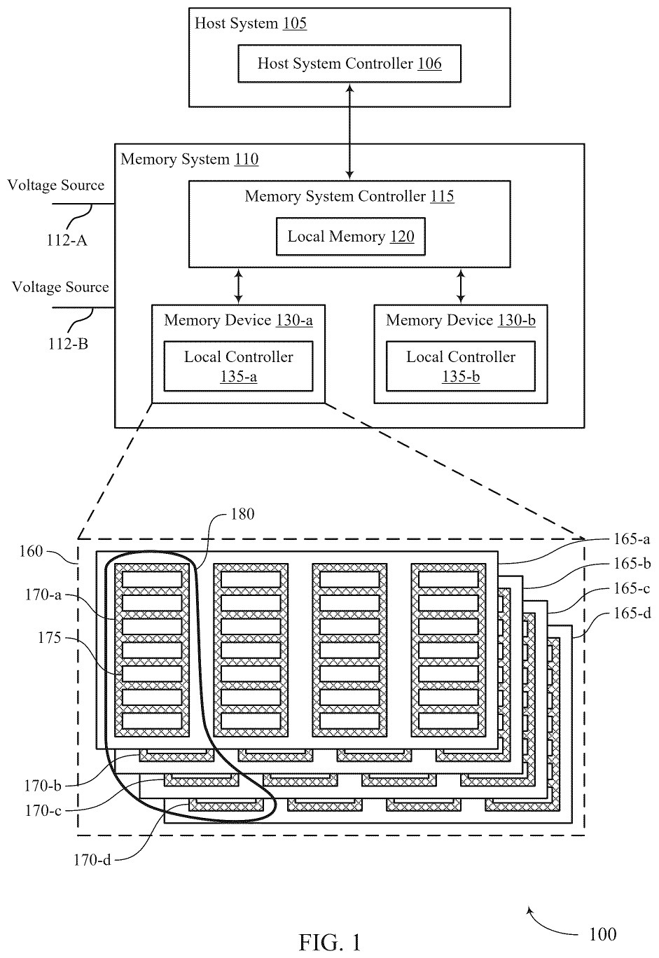

FIG. 1 shows an example of a system 100 that supports techniques for initialization in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset (e.g., one or more processors) may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 (e.g., one or more processors embedded at the memory system 110) and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135 (e.g., one or more local controllers 135 or one or more processors), which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

The system 100 may include any quantity of non-transitory computer readable media that support techniques for NAND initialization. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

In some systems, the memory system 110 may perform one or more initialization procedures (e.g., after power up or after exiting a sleep state) at one or more dies 160 to prepare the dies 160 for use by one or more controllers (e.g., the memory system controller 115, local controllers 135, or both) of the memory system 110. For example, the memory system 110 may be coupled with a voltage source 112-a (e.g., Vcc) and a voltage source 112-b (e.g., Vccq), where the voltage source 112-a may provide power to the memory system 110 (and memory devices 130) and the voltage source 112-b may provide power to the one or more controllers of the memory system 110 (e.g., the memory system controller 115, local controllers 135, or both). As such, in response to or based on the voltages sources 112 satisfying a threshold (e.g., voltage sources reaching a ready state) the one or more controllers may perform a wakeup procedure (e.g., ASIC wakeup procedure). In some systems, in response to or based on performing the wakeup procedure, the one or more controllers may transmit a respective command to each of the one or more dies 160 to trigger the one or more dies 160 to perform the initialization procedure. However, such serialized performance of the wakeup procedure and the initialization procedure (e.g., the wakeup procedure at the controllers is completed prior to the start of the initialization procedure at the dies 160) may cause an increase in startup delays at the memory system 110. Such startup delays may occur each time the memory system 110 exits the sleep state, thereby increasing performance delays and latency of the memory system. As such, solutions which reduce startup delays in memory systems are desirable.

Techniques described herein may enable one or more dies 160 of the memory system 110 to perform an automatically-triggered initialization procedure prior to one or more controllers (e.g., local controllers 135, a memory system controller 115, or both) completing a wakeup procedure, thereby reducing latency associated with startup. For example, a host system may power the memory system from an idle state (e.g., a sleep state) using the voltage source 112-a, the voltage source 112-b (e.g., Vccq), or both. Accordingly, the one or more dies 160 may perform an initialization procedure in response to or based on a voltage level of the voltage source 112-a satisfying a first threshold (e.g., Vcc reaching a ready state), in response to or based on a voltage level of the voltage source 112-b satisfying a second threshold (e.g., Vccq reaching a ready state), or both. After, or in conjunction with, the initialization procedure, the one or more controllers may perform a wakeup procedure (e.g., an ASIC wakeup procedure) in response to or based on powering the memory system 110. In some cases, the one or more controllers may perform the wakeup procedure after a start of the initialization procedure at the one or more dies 160. In some other cases, the one or more controllers may perform the wakeup procedure and the one or more dies 160 may perform the initialization procedure simultaneously. In this way, the one or more dies 160 may perform the initialization procedure before an end of the wakeup procedure at the one or more controllers, thereby reducing startup delays, among other benefits.

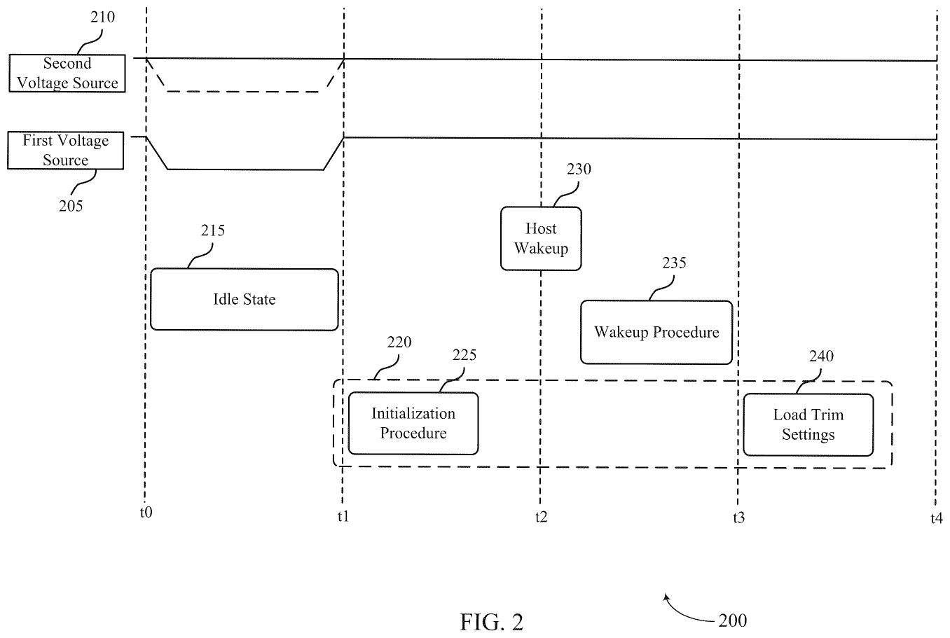

FIG. 2 shows an example of a timing diagram 200 that supports techniques for non-volatile memory, such as NAND memory, initialization in accordance with examples as disclosed herein. The timing diagram 200 may implement, or be implemented by, aspects or operations of the system 100 as described herein with reference to FIG. 1. For example, aspects of the timing diagram 200 may be implemented at the memory system 110 (e.g., including one or more memory devices 130). Additionally, or alternatively, aspects of the timing diagram 200 may be implemented as instructions stored in one or more memories (e.g., firmware stored in one or more memories coupled with the memory system 110). For example, the instructions, when executed by one or more controllers (e.g., local controllers 135, the memory system controller 115, or both) may cause the one or more controllers (or a device or a system) to perform the operations of the timing diagram 200. Additionally, the memory system 110 may be coupled with a first voltage source 205 (e.g., Vcc) and a second voltage source 210 (e.g., Vccq), which may respectively correspond with the voltage source 112-a and the voltage source 112-b as described herein with reference to FIG. 1.

In some systems (e.g., managed NAND systems), in direct response to transitioning from an idle state 215 to an awake state, one or more controllers of the memory system 110 may perform a wakeup procedure 235. For example, in response to or based on the powering of the memory system 110 (e.g., Vcc, Vccq power cycle) or transitioning from a sleep or hibernate state (Vcc power cycle, Vccq on always), the one or more controllers of the memory system 110 may perform the wakeup procedure 235, which may span a duration of 200-400 microseconds (us) for example. In response to or based on completion of the wakeup procedure 235, the one or more controllers may transmit a command (e.g., an FFh command or reset command) to one or more dies 160 (e.g., NAND dies), where the command may trigger each of the one or more dies 160 to perform an initialization procedure 225, which may span a duration of 600 us-1 millisecond (ms) for example. In response to or based on completion of the initialization procedure 225, the one or more controllers may continue to configure each of the one or more dies 160, for example, by loading trim settings 240 at each of the one or more dies 160. In such systems, however, such serialized operations (e.g., the wakeup procedure 235 completing prior to the performance of the initialization procedure 225 and loading the trim settings 240) may span a duration of 3 ms-10 ms for example, which may cause an increase in startup delays at the memory system 110. Such startup delays may occur each time the memory system 110 transitions from the idle state 215 to the awake state, thus increasing performance delays and latency of the memory system 110.

Accordingly, to reduce the latency in the memory system 110, the one or more dies 160 may be triggered to perform the initialization procedure 225 in response to or based on the first voltage source 205 satisfying a threshold (e.g., Vcc reaching a ready state), the second voltage source 210 satisfying a threshold (e.g., Vccq reaching a ready state), or both. As such, the duration to perform the initialization procedure 225 (e.g., NAND tPOR) may be masked by performing the initialization procedure 225 in parallel, or prior to, the performance of the wakeup procedure 235. By performing the initialization procedure 225 prior to, or in parallel with, the wakeup procedure 235, the memory system 110 may reduce the wake-up time (e.g., Vcc power cycle time), thereby reducing latency during startup procedures in the memory system 110 and the host system 105 (e.g., automotive products, mobile devices, or the like), among other advantages and applications.

For example, the memory system 110 may be operating in the idle state 215 (e.g., a hibernating state, a sleep state, or an “off” state) if at least one of the first voltage source 205 or the second voltage source 210 has not satisfied a respective threshold (e.g., if the first voltage source 205 or the second voltage source 210 have not reached a ready state or are outputting a “low” or an “off” signal). The memory system may be in the idle state 215 from t0 to t1. In such examples, the memory system 110 may operate in an hibernate or sleep mode if the first voltage source 205 outputs a low signal from t0 until t1, while the second voltage source 210 outputs a ready signal (e.g., an “on” signal or a high signal) from t0 until t1. Alternatively, the memory system 110 may be in an “off” state from t0 to t1 if both the first voltage source 205 and the second voltage source 210 output a low signal (e.g., an “off” signal).

In some examples, prior to, or in conjunction with, operating in the idle state 215, the one or more controllers of the memory system 110 may receive a command from the host system 105 to perform an ASIC preparation procedure (not shown). Accordingly, the one or more controllers of the memory system 110 may load trim settings or configurations from one or more dies 160 and construct (e.g., build or generate) NAND trim images, where such ASIC preparation procedures may not involve the one or more dies 160. In response to or based on completing the ASIC preparation procedure, the one or more controllers may transmit an acknowledgment (ACK) to the host system 105 indicating that the ASIC preparation has completed.

In some implementations, the one or more dies 160 may perform a set of startup operations 220. For example, in response to or based on the first voltage source 205 reaching a ready state, the second voltage source 210 reaching a ready state, or both, (e.g., if the voltage sources satisfy a threshold, or output a “high” signal), the one or more dies 160 may begin the initialization procedure 225 (e.g., at t1). In such examples, the one or more dies 160 may be coupled with the first voltage source 205 and the second voltage source 210 via respective pads or fuses, such as with an RST_N fuse. Accordingly, in response to or based on detecting that the voltage level of the first voltage source 205, the voltage level of the second voltage source 210, or both, have satisfied a voltage threshold (e.g., reached a ready state, satisfied a voltage value, or the like), each of the one or more dies 160 may begin the initialization procedure 225. In such examples, as part of the initialization procedure 225, the one or more dies 160 may power on and perform one or more plane read operations. For example, a memory device 130 (including the one or more dies 160) may perform a read operation on one or more planes 165 of a die 160 during the initialization procedure 225.

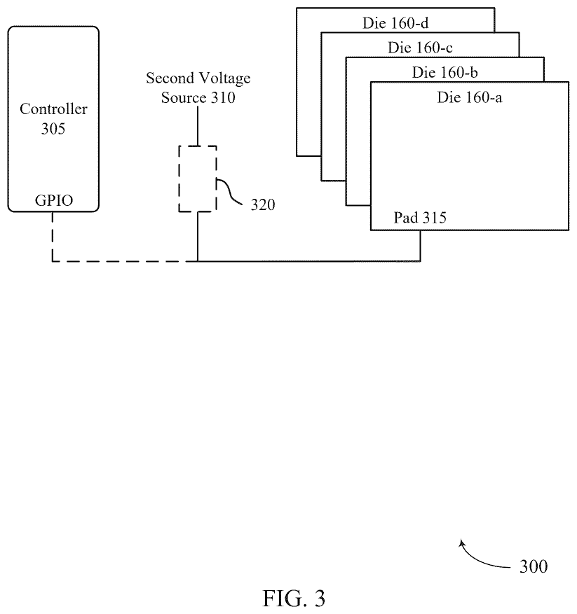

In some examples, the one or more dies 160 may monitor a pad (e.g., ZQ or DBI) to determine whether to perform an automatic trigger of the initialization procedure 225. For example, if the one or more dies 160 detect that a signal exceeds a threshold, the one or more dies 160 may perform the automatic triggering of the initialization procedure 225. Techniques to enable the automatic triggering of the initialization procedure 225 may be further described herein with reference to FIG. 3.

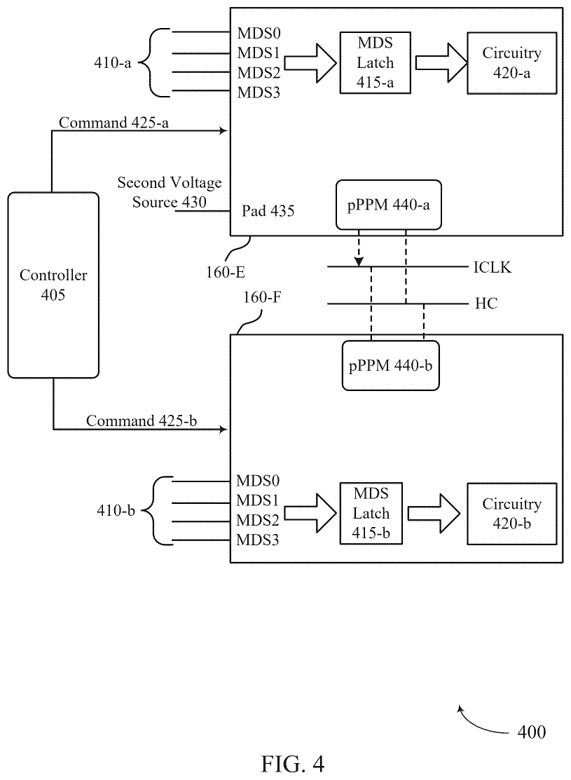

In some examples, the memory system 110 may stagger the performance of the initialization procedure 225 between each die 160 of the one or more dies 160 to limit the total current drawn at the memory system 110. For example, a first die 160 may perform the initialization procedure 225 during a first duration, and a second die 160 may perform the initialization procedure 225 during a second duration after the first duration. Techniques to limit the total current drawn at the memory system during the initialization procedure 225 may be further described herein with reference to FIG. 4.

As described herein, the one or more dies 160 may perform the initialization procedure 225 prior to, or in conjunction with, a host wakeup procedure 230 and the wakeup procedure 235 (e.g., an ASIC wakeup procedure). For example, in response to or based on transitioning from the idle state 215, the host system 105 may perform the host wakeup procedure 230. Similarly, the one or more controllers may perform the wakeup procedure 235 in response to or based on the transition from the idle state 215. In response to or based on completing the wakeup procedure 235, the one or more controllers of the memory system 110 may load (e.g., write) a set of trim settings to the one or more dies 160. In this way, the one or more dies 160 may perform the initialization procedure 225 prior to, or in conjunction with, the wakeup procedure 235, thereby reducing the latency at the memory system 110 during transitions from the idle state 215 to the awake state.

FIG. 3 shows an example of a memory device architecture 300 that supports techniques for non-volatile memory, such as NAND memory, initialization in accordance with examples as disclosed herein. The memory device architecture 300 may implement, or be implemented by, aspects or operations of the system 100 and the timing diagram 200, as described herein with reference to FIGS. 1 and 2. For example, aspects of the memory device architecture 300 may be implemented at one or more memory devices 130 of the memory system 110. The memory device architecture 300 may include a controller 305 and one or more dies 160 (e.g., dies 160-a, 160-b, 160-c, and 160-d). The controller 305 may be an example of a memory system controller 115, a local controller 135, or another controller (e.g., an ASIC). The memory device architecture 300 may be configured to reduce delays associated with performing initialization procedures in memory systems 110.

As described herein, because auto-triggering of the initialization procedure 225 may be implemented in hardware in some examples (e.g., in response to or based on Vcc, Vccq, or both reaching a ready state), each of the one or more dies 160 may not have an indication of whether the auto-triggering of the initialization procedure 225 is enabled (e.g., each die 160 may not have an indication if auto-triggering is on or off right after power up). For example, because the initialization procedure 225 may be performed prior to, or in conjunction with, the wakeup procedure 235, the one or more controllers of the memory system 110 may be unable to transmit any commands during the wakeup procedure 235. Accordingly, techniques may be desired to indicate to each of the dies 160 whether the auto-triggering of the initialization procedure 225 is enabled prior to transitioning from the idle state 215 to the awake state.

In some implementations, during manufacturing, a second voltage source 310 (e.g., Vccq, the second voltage source 210, the voltage source 112-b) may be pre-bonded (e.g., pre-connected) to a pad 315 of each die 160 of the one or more dies 160. The pad 315 may be an example of a ZQ pad or a DBI pad. In such implementations, the one or more dies 160 may enable or disable the automatic triggering of an initialization procedure (e.g., the initialization procedure 225) in response to or based on a voltage level for the pad 315.

In some examples, the pad 315 of each die 160 may be directly coupled with the second voltage source 310. In such examples, each die 160 may enable the automatic triggering of the initialization procedure 225 in response to or based on a voltage level of the pad 315 exceeding a threshold (e.g., the voltage level of the pad is high), where the voltage level of the pad 315 is in response to or based on the second voltage source 310 exceeding a threshold (e.g., reaching a “ready” state). Alternatively, if the one or more dies 160 detect that the voltage level at the pad 315 does not exceed the threshold (e.g., the voltage level of the pad 315 is floating or low), the one or more dies 160 may perform the initialization procedure 225 after one or more wakeup procedures (e.g., after the host wakeup procedure 230, the wakeup procedure 235, or both). In such cases, the one or more dies 160 may refrain from performing (e.g., wait to perform, delay performing) the initialization procedure 225 until a trigger event, such as receiving a command from the controller 305.

In some other examples, a general purpose input/output (GPIO) of the controller 305 may be coupled with the pad 315, while the pad 315 also may be coupled with the second voltage source 310 via a pull up resistor 320. In such examples, if the pad 315 on each die 160 is pulled up (e.g., is biased to high via internal and external pull up resistors including the pull up resistor 320), the pad 315 may have a high logic state (e.g., the voltage level at the pad 315 may exceed a threshold) indicating to the dies 160 to perform the auto-triggered procedure. If the pad 315 on the die 160 is not pulled up, the pad 315 may have a low logic state (e.g., the voltage level at the pad 315 may not exceed a threshold), indicating that the one or more dies 160 may refrain from performing the initialization procedure until after the one or more wakeup procedures (e.g., after the host wakeup, the controller wakeup, or both). In this way, if the controller 305 has power prior during the idle state 215 of the memory system 110, the controller 305 may be able to bias the pad 315 of each of the dies 160 to enable or disable the automatic-triggering of the initialization procedure 225.

After completion of the initialization procedure 225, the memory system 110 (e.g., via the controller 305) may re-configure (e.g., re-purpose) each pad 315 of the one or more dies 160 to perform default operations. For example, the one or more dies 160 may use respective pads 315 to perform data communication after performing the initialization procedure 225. That is, the respective pads 315 of each of the dies 160 may also be coupled with one or more data lines. Accordingly, in response to or based on completion of the initialization procedure 225 at each of the dies 160, the dies 160 may monitor the data line via the pads 315.

FIG. 4 shows an example of a memory device architecture 400 that supports techniques for non-volatile memory, such as NAND memory, initialization in accordance with examples as disclosed herein. Aspects of the memory device architecture 400 may implement, or be implemented by, aspects of the system 100, the timing diagram 200, and the memory device architecture 300, as described herein with reference to FIGS. 1-3. For example, the memory device architecture 400 may be implemented in one or more memory devices 130 of the memory system 110 and include a controller 405 (e.g., the memory system controller 115, local controllers 135, or both) and one or more dies 160 (e.g., a die 160-e and a die 160-f). The techniques described in the context of the memory device architecture 400 may enable the memory system 110 to control (e.g., stagger or throttle) a peak current of the memory system 110 during the initialization procedure 225 of the one or more dies 160.

In some systems (e.g., memory systems 110 without a memory system controller 115), the host system 105 may manually stagger the initialization procedure at each of the dies 160 via reset commands. For example, the host system 105 may transmit a reset command (not shown) to each of the dies 160 of the memory system 110 according to a fixed delay, where the command triggers each of the dies 160 to perform the initialization procedure 225. By doing so, the host system 105 may have flexibility in deciding the quantity of dies 160 that are to perform the initialization procedure 225 at a given time (e.g., by staggering the transmission of the reset commands to one or more dies 160). If each die 160 performed the initialization procedure 225 at the same time (e.g., if the voltage sources reached a ready state), the memory system 110 may experience a brown out (e.g., reach a maximum or peak current).

Accordingly, by having the host system 105 issue the reset commands (e.g., FFh commands), the host system 105 may control which dies 160 to initialize, thereby limiting the peak current at the memory system 110. Further, as the quantity of dies 160 in the memory system 110 increases, the likelihood of drawing a peak current during the initialization procedure 225 may increase. In such systems, a local controller 135 of a memory device 130 may load a block, such as a ROM block, prior to the dies 160 beginning the initialization procedure 225 (e.g., during the tPOR time) via internal read operations triggered by the reset command. Such techniques (e.g., manually transmitting reset commands) may control the peak current of the memory system 110 in response to or based on whether the delay between reset commands is aligned with the peak current period of the initialization procedure (e.g., NAND initialization algorithm), which may be inaccurate between different NAND products and designs. That is, because the delays between transmitting each reset command are fixed at the host system 105 (e.g., via ROM in the host system), such techniques may be inaccurate across different memory systems 110.

Alternatively, in some other systems, each die 160 may self-stagger the performance of the initialization procedure 225 according to logic values across a set of multi-die select (MDS) pads 410 (e.g., MDS0-MDS3 at each die 160). For example, in response to or based on receiving a reset command from the host system 105, each die 160 may detect a respective logic value at each MDS pad of the set of MDS pads 410 (e.g., a high voltage equates to a logical ‘1’ while a low voltage equates to a logical ‘0’, or vice versa), where the logic values of the set of MDS pads 410 indicate a logical unit number (LUN) of the die 160 (e.g., a respective identifier of each die 160). Accordingly, each die 160 may automatically stagger the performance of the initialization procedure 225 according to a delay relative to the reception time of the reset command in response to or based on the logic values of the set of MDS pads 410. Table 1 illustrates an example of logic values of the set of MDS pads 410 and associated delays:

TABLE 1
MDS Values and Associated Delays

| Package | Chip | | | | | Delay | |
|---|---|---|---|---|---|---|---|
| Configu- | Enable | | | | | Relative To | |
| ration | (CE#) | MDS3 | MDS2 | MDS1 | MDS0 | RESET | |
| LUN0 | CE# | 1 | 1 | 0 | 1 | 0 | |
| LUN1 | CE# | 1 | 1 | 0 | 0 | X | us |
| LUN2 | CE# | 1 | 0 | 0 | 1 | 2*X | us |
| LUN3 | CE# | 1 | 0 | 0 | 0 | 3*X | us |

As an illustrative example, the die 160-e may identify that the logic values across the MDS pads 410 are set to be LUN1 (e.g., 1100). Accordingly, the die 160-e may start (e.g., begin) the initialization procedure 225 X us after receiving the receiving the reset command. In this way, the dies 160 may identify a respective delay based on the logic values across respective MDS pads 410.

However, the memory system 110 (e.g., MNAND systems) may be unable to use such techniques in staggering the initialization procedure 225 at each die 160. For example, because the initialization procedure 225 is performed prior to, or in conjunction with, the wakeup procedure 235 of the one or more controllers of the memory system 110 and the host wakeup procedure 230 of the host system 105, the dies 160 may not receive reset commands staggering the performance of the initialization procedure 225, resulting in each die 160 performing the initialization procedure 225 at a same time. Further, in MNAND systems, there may be eight dies 160 per chip enable and each die 160 may be bonded to a same LUN (e.g., LUNO). That is, in MNAND systems, the logic values of the set of MDS pads 410 at each die 160 may be bonded (e.g., set) to a same value during the initialization procedure 225, resulting in each of the dies 160 being unable to perform self-staggering. Accordingly, if each of the eight dies 160 performs the initialization procedure at a same time, the memory system 110 may draw a current of eight times the value of current used for performing the initialization procedure. For example, the memory system 110 may draw a current of 8*I milliamps (mA) (e.g., 8 die*I mA per initialization procedure=8*I mA). Thus, if the peak current of the memory system 110 is 500 mA (due to mobile USB charging limit), the memory system 110 may experience brown outs.

In some implementations, to be able to perform the auto-triggering of the initialization procedure 225, as described herein with reference to FIG. 2, and limit the peak current drawn during the initialization procedure at each die 160, each of the dies 160 may perform two single plane read operations, where a second of the two single plane read operations is staggered (e.g., delayed) relative to a first single plane read operation. For example, during the initialization procedure 225, the die 160-e may perform a first single plane read operation, stagger a second single plane read operation by a delay, and perform the second single plane read operation in response to or based on expiration of the delay. By doing so, the current drawn due to staggering the single plane read operations at each of the dies 160 may be lower than a current threshold (e.g., peak current) of the memory system 110.

In some other implementations, each of the set of MDS pads 410 at the dies 160 may be bonded to various voltage levels corresponding to respective LUNS during the initialization procedure 225, such that each die 160 may identify a respective delay of the initialization procedure 225 according to the logic values across each set of MDS pads 410. In such implementations, after completion of the initialization procedure 225, a MDS latch 415 at each die 160 may be overwritten, such that the LUNs of each die 160 to be a default value (e.g., LUN0).

For example, prior to triggering the initialization procedure 225, each set of MDS pads 410 of the dies 160 may be bonded to voltage levels representative of a respective LUN (e.g., LUN0-LUN7). As an illustrative example, the set of MDS pads 410-a at the die 160-e may be bonded to a first LUN, such as 1101 or LUN0, while the set of MDS pads 410-b at the die 160-f may be bonded to a second LUN, such as 1000 or LUN3. Accordingly, in response to or based on the first voltage source, the second voltage source, or both satisfying a threshold (e.g., reaching a ready state), a MDS latch 415 at each die 160 may transmit the LUNs, as bonded at the set of MDS pads 410, to circuitry 420, where circuitry 420 may identify a respective delay for the initialization procedure 225 according to the respective LUNs.

In some examples, the circuitry 420-a may receive, from the MDS latch 415-a, a LUN value of 1000 and may identify a delay for the initialization procedure 225 at the die 160-e to be 0 us (according to Table 1). Similarly, the circuitry 420-b may receive, from the MDS latch 415-b, a LUN value of 1000 and may identify a delay for the initialization procedure 225 at the die 160-f to be 3*X us (according to Table 1).

In response to or based on identifying the delay, each die 160 may perform the initialization procedure 225 according to the respective delays, where the respective delays may be relative to the first voltage source, the second voltage source, or both satisfying a threshold. For example, the die 160-e may have a delay of 0 us, and thus perform the initialization procedure 225 in response to or based on identifying the first voltage source, the second voltage source, or both have satisfied the threshold. While the die 160-f may have a delay of 3*X us, and thus perform the initialization procedure 225 after 3*X us from identifying the first voltage source, the second voltage source, or both have satisfied the threshold. As described herein, the dies 160 may perform the initialization procedure 225 in parallel with the controller 405 performing the wakeup procedure 235.

In response to or based on completion of the initialization procedure 225 at each die 160 and the completion of the wakeup procedure 235 at the controller 405, the controller 405 (e.g., MNAND firmware) may write a command 425 to each of the dies 160 to reconfigure each MDS latch 415 back to a first LUN value (e.g., default value, LUNO). For example, the controller 405 may transmit the command 425-a to the die 160-e indicating for the MDS latch 415-a to be set to the first LUN value. Similarly, the controller 405 may transmit the command 425-b to the die 160-f indicating for the MDS latch 415-b to be set to the first LUN value. The controller 405 may transmit a command 425 to each die 160 of the memory system 110, such that the MDS latch 415 of all dies 160 of the memory system 110 (e.g., MNAND system) are configured as LUN0. In this way, the dies 160 may stagger the performance of the initialization procedure 225, thereby limiting the peak current at the memory system 110.

In some other implementations, each die 160 may perform the initialization procedure 225 according to a randomized delay, where the randomized delay is according to device information associated with each of the dies 160. Such device information may include a position of the die 160 in the memory system 110 (e.g., an X/Y location of the die 160 on the wafer) and be stored in a fuse of the memory system 110 or ROM of the memory system 110. For example, according to the device information associated with each of the dies 160, each of the dies 160 may generate a respective delay and stagger the performance of the initialization procedure 225 accordingly.

In some implementations, during the initialization procedure 225, a programmable peak power manager (pPPM) 440 (e.g., a pPPM 440-a and a pPPM 440-b) at each die 160 may communicate current operating current levels on an HC bus, such that the pPPM 440 of each die 160 may identify at what time to perform the initialization procedure 225 according to a sum of the operating currents at each of the dies 160. For example, the memory system 110 may have a current threshold (e.g., a default budget or peak current threshold, such as 500 mA or 800 mA). Accordingly, the pPPM 440 of each die 160 may communicate the operating currents on the HC bus, where the pPPM 440 of each die 160 may calculate the total operating current across all the dies 160 (e.g., a sum of all the currents transmitted on the HC bus). If the sum of the operating currents is less than the current threshold, a first die 160 may begin the initialization procedure 225, while also continuing to communicate the operating current to the other dies 160. One or more additional dies 160 may also begin the initialization procedure 225 and continue to communicate the operating currents to the other dies 160. According to the sum of the operating currents satisfying the current threshold (e.g., reaching or exceeding), the other dies 160 may refrain from performing the initialization procedure or stop performing the initialization procedure 225 (if already begun) to limit the peak current at the memory system 110.

To facilitate such communication over the HC bus, one of the dies 160 may be selected as the master die 160, where pPPM 440 of the master die drives (e.g., controls) the clock (ICLK) for the pPPMs 440 of the slave dies 160. For example, the die 160-e may have a pad 435 (e.g., ZQ or DBI pad) bonded to the second voltage source 430 (e.g., Vccq). Accordingly, in response to or based on the first voltage source, the second voltage source, or both, satisfying a threshold, the voltage level of the pad 435 may be bonded to a high voltage level, thereby indicating that the die 160 is the master die 160. Accordingly, the pPPM 440-a of the die 160-a may drive the clock to the other dies 160, such that each die 160 may communicate the respective operating currents.

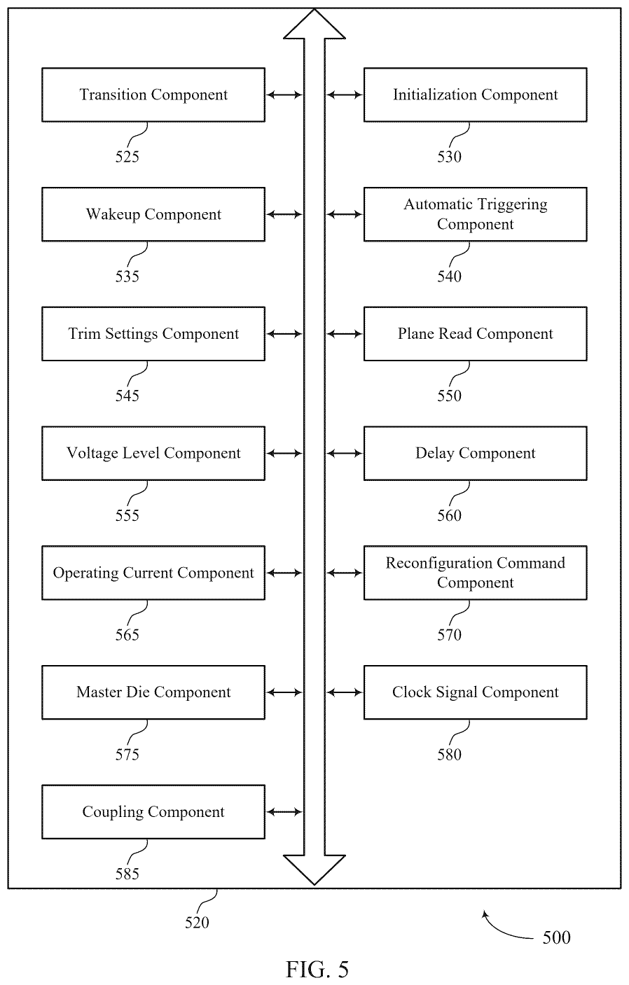

FIG. 5 shows a block diagram 500 of a memory system 520 that supports techniques for non-volatile memory, such as NAND memory, initialization in accordance with examples as disclosed herein. The memory system 520 may be an example of aspects of a memory system as described with reference to FIGS. 1 through 4. The memory system 520, or various components thereof, may be an example of means for performing various aspects of techniques for NAND initialization as described herein. For example, the memory system 520 may include a transition component 525, an initialization component 530, a wakeup component 535, an automatic triggering component 540, a trim settings component 545, a plane read component 550, a voltage level component 555, a delay component 560, an operating current component 565, a reconfiguration command component 570, a master die component 575, a clock signal component 580, a coupling component 585, or any combination thereof. Each of these components, or components of subcomponents thereof (e.g., one or more processors, one or more memories), may communicate, directly or indirectly, with one another (e.g., via one or more buses).

The transition component 525 may be configured as or otherwise support a means for transitioning a memory system from an idle state to an awake state based at least in part on a voltage level of a first voltage source, the memory system including one or more controllers and one or more NAND dies. The initialization component 530 may be configured as or otherwise support a means for performing, during a first duration, an initialization procedure of the one or more NAND dies based at least in part on the voltage level of the first voltage source satisfying a threshold. The wakeup component 535 may be configured as or otherwise support a means for performing, during a second duration that begins after a start of the initialization procedure, a wakeup procedure to wake up the one or more controllers based at least in part on transitioning the memory system from the idle state to the awake state.

In some examples, the automatic triggering component 540 may be configured as or otherwise support a means for determining whether to enable automatic triggering of the initialization procedure based at least in part on a voltage level of a respective pad of one of the one or more NAND dies, where performing the initialization procedure is based at least in part on determining to enable the automatic triggering of the initialization procedure after the voltage level of the respective pad satisfies a second threshold.

In some examples, the voltage level of the respective pad of the one or more NAND dies is based at least in part on a voltage level of a second voltage source, a respective GPIO pin of the one or more controllers, or both.

In some examples, the coupling component 585 may be configured as or otherwise support a means for reconfiguring the respective pad of the one or more NAND dies from being coupled with to the second voltage source to being coupled with a data line based at least in part on completion of the initialization procedure at the one or more NAND dies.

In some examples, the trim settings component 545 may be configured as or otherwise support a means for receiving, at the one or more NAND dies, a set of trim settings from the one or more controllers based at least in part on a completion of the wakeup procedure.

In some examples, to support performing the initialization procedure of the one or more NAND dies, the plane read component 550 may be configured as or otherwise support a means for staggering a second plane read operation by a delay relative to performing a first plane read operation based at least in part on a peak operating current of the memory system during the initialization procedure. In some examples, to support performing the initialization procedure of the one or more NAND dies, the plane read component 550 may be configured as or otherwise support a means for performing the second plane read operation based at least in part on expiration of the delay.

In some examples, the voltage level component 555 may be configured as or otherwise support a means for setting, during the transition of the memory system from the idle state to the awake state, voltage levels of a respective set of MDS pads at each of the one or more NAND dies, where the voltage levels of the respective set of MDS pads indicate a respective identifier for each of the one or more NAND dies. In some examples, the initialization component 530 may be configured as or otherwise support a means for staggering the performance of the initialization procedure between each of the one or more NAND dies according to a respective delay for each of the one or more NAND dies, where the respective delay for each of the one or more NAND dies is based at least in part on the respective identifier of each of the one or more NAND dies.

In some examples, the reconfiguration command component 570 may be

configured as or otherwise support a means for receiving, at the one or more NAND dies and based at least in part on a completion of the initialization procedure, a respective command to reconfigure the respective identifiers for each of the one or more NAND dies to a default value.

In some examples, the delay component 560 may be configured as or otherwise support a means for generating, for each of the one or more NAND dies, a respective delay based at least in part on respective device information associated with each of the one or more NAND dies. In some examples, the initialization component 530 may be configured as or otherwise support a means for staggering the performance of the initialization procedure between each of the one or more NAND dies according to the respective delay of each of the one or more NAND dies.

In some examples, the respective device information includes a respective position of each of the one or more NAND dies.

In some examples, the respective device information for each of the one or more NAND dies is stored in a respective fuse, in a respective portion of ROM, or both.

In some examples, the operating current component 565 may be configured as or otherwise support a means for communicating, during the first duration and between each of the one or more NAND dies, operating currents of each of the one or more NAND dies, where performance of the initialization procedure at each of the one or more NAND dies is based at least in part on a sum of the operating currents of each of the one or more NAND dies.

In some examples, the master die component 575 may be configured as or otherwise support a means for identifying that a first NAND die of the one or more NAND dies is a master die based at least in part on a voltage level of a pad of the first NAND die satisfying a second threshold. In some examples, the clock signal component 580 may be configured as or otherwise support a means for transmitting, by the first NAND die to at least a second NAND die of the one or more NAND dies, a clock signal, where communicating the operating currents of each of the one or more NAND dies is in accordance with the clock signal transmitted from the first NAND die.

In some examples, the performance of the initialization procedure is further based at least in part on a voltage level of a second voltage source satisfying a second voltage threshold.

In some examples, the idle state includes a hibernate state or an off state.

In some examples, the described functionality of the memory system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 520, or various components thereof, may be implemented at least in part by instructions (e.g., stored in memory, non-transitory computer-readable medium) executable by such at least one processor.

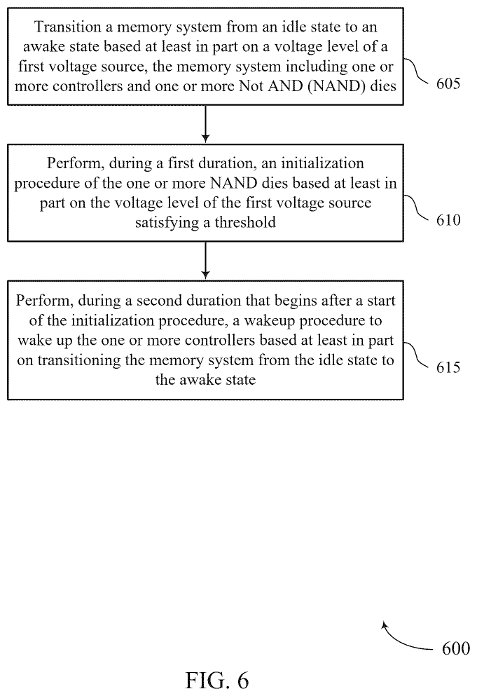

FIG. 6 shows a flowchart illustrating a method 600 that supports techniques for non-volatile memory, such as NAND memory, initialization in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include transitioning a memory system from an idle state to an awake state based at least in part on a voltage level of a first voltage source, the memory system including one or more controllers and one or more NAND dies. In some examples, aspects of the operations of 605 may be performed by a transition component 525 as described with reference to FIG. 5.

At 610, the method may include performing, during a first duration, an initialization procedure of the one or more NAND dies based at least in part on the voltage level of the first voltage source satisfying a threshold. In some examples, aspects of the operations of 610 may be performed by an initialization component 530 as described with reference to FIG. 5.

At 615, the method may include performing, during a second duration that begins after a start of the initialization procedure, a wakeup procedure to wake up the one or more controllers based at least in part on transitioning the memory system from the idle state to the awake state. In some examples, aspects of the operations of 615 may be performed by a wakeup component 535 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for transitioning a memory system from an idle state to an awake state based at least in part on a voltage level of a first voltage source, the memory system including one or more controllers and one or more NAND dies; performing, during a first duration, an initialization procedure of the one or more NAND dies based at least in part on the voltage level of the first voltage source satisfying a threshold; and performing, during a second duration that begins after a start of the initialization procedure, a wakeup procedure to wake up the one or more controllers based at least in part on transitioning the memory system from the idle state to the awake state.

Aspect 2: The method, apparatus, or non-transitory computer-readable medium of aspect 1, further including operations, features, circuitry, logic, means, or instructions, or any combination thereof for determining whether to enable automatic triggering of the initialization procedure based at least in part on a voltage level of a respective pad of one of the one or more NAND dies, where performing the initialization procedure is based at least in part on determining to enable the automatic triggering of the initialization procedure after the voltage level of the respective pad satisfies a second threshold.

Aspect 3: The method, apparatus, or non-transitory computer-readable medium of aspect 2, where the voltage level of the respective pad of the one or more NAND dies is based at least in part on a voltage level of a second voltage source, a respective GPIO pin of the one or more controllers, or both.

Aspect 4: The method, apparatus, or non-transitory computer-readable medium of aspect 3, further including operations, features, circuitry, logic, means, or instructions, or any combination thereof for reconfiguring the respective pad of the one or more NAND dies from being coupled with to the second voltage source to being coupled with a data line based at least in part on completion of the initialization procedure at the one or more NAND dies.

Aspect 5: The method, apparatus, or non-transitory computer-readable medium of any of aspects 1 through 4, further including operations, features, circuitry, logic, means, or instructions, or any combination thereof for receiving, at the one or more NAND dies, a set of trim settings from the one or more controllers based at least in part on a completion of the wakeup procedure.

Aspect 6: The method, apparatus, or non-transitory computer-readable medium of any of aspects 1 through 5, where performing the initialization procedure of the one or more NAND dies includes operations, features, circuitry, logic, means, or instructions, or any combination thereof for staggering a second plane read operation by a delay relative to performing a first plane read operation based at least in part on a peak operating current of the memory system during the initialization procedure and performing the second plane read operation based at least in part on expiration of the delay.

Aspect 7: The method, apparatus, or non-transitory computer-readable medium of any of aspects 1 through 6, further including operations, features, circuitry, logic, means, or instructions, or any combination thereof for setting, during the transition of the memory system from the idle state to the awake state, voltage levels of a respective set of MDS pads at each of the one or more NAND dies, where the voltage levels of the respective set of MDS pads indicate a respective identifier for each of the one or more NAND dies; where performing the initialization procedure includes; and staggering the performance of the initialization procedure between each of the one or more NAND dies according to a respective delay for each of the one or more NAND dies, where the respective delay for each of the one or more NAND dies is based at least in part on the respective identifier of each of the one or more NAND dies.

Aspect 8: The method, apparatus, or non-transitory computer-readable medium of aspect 7, further including operations, features, circuitry, logic, means, or instructions, or any combination thereof for receiving, at the one or more NAND dies and based at least in part on a completion of the initialization procedure, a respective command to reconfigure the respective identifiers for each of the one or more NAND dies to a default value.

Aspect 9: The method, apparatus, or non-transitory computer-readable medium of any of aspects 1 through 8, further including operations, features, circuitry, logic, means, or instructions, or any combination thereof for generating, for each of the one or more NAND dies, a respective delay based at least in part on respective device information associated with each of the one or more NAND dies, where performing the initialization procedure includes and staggering the performance of the initialization procedure between each of the one or more NAND dies according to the respective delay of each of the one or more NAND dies.

Aspect 10: The method, apparatus, or non-transitory computer-readable medium of aspect 9, where the respective device information includes a respective position of each of the one or more NAND dies.

Aspect 11: The method, apparatus, or non-transitory computer-readable medium of any of aspects 9 through 10, where the respective device information for each of the one or more NAND dies is stored in a respective fuse, in a respective portion of ROM, or both.

Aspect 12: The method, apparatus, or non-transitory computer-readable medium of any of aspects 1 through 11, further including operations, features, circuitry, logic, means, or instructions, or any combination thereof for communicating, during the first duration and between each of the one or more NAND dies, operating currents of each of the one or more NAND dies, where performance of the initialization procedure at each of the one or more NAND dies is based at least in part on a sum of the operating currents of each of the one or more NAND dies.

Aspect 13: The method, apparatus, or non-transitory computer-readable medium of aspect 12, further including operations, features, circuitry, logic, means, or instructions, or any combination thereof for identifying that a first NAND die of the one or more NAND dies is a master die based at least in part on a voltage level of a pad of the first NAND die satisfying a second threshold and transmitting, by the first NAND die to at least a second NAND die of the one or more NAND dies, a clock signal, where communicating the operating currents of each of the one or more NAND dies is in accordance with the clock signal transmitted from the first NAND die.

Aspect 14: The method, apparatus, or non-transitory computer-readable medium of any of aspects 1 through 13, where the performance of the initialization procedure is further based at least in part on a voltage level of a second voltage source satisfying a second voltage threshold.

Aspect 15: The method, apparatus, or non-transitory computer-readable medium of any of aspects 1 through 14, where the idle state includes a hibernate state or an off state.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices including one or more not-and (NAND) dies; and
one or more controllers coupled with the one or more memory devices and configured to cause the memory system to:
transition the memory system from an idle state to an awake state in accordance with a voltage level of a first voltage source;
perform, during a first duration, an initialization procedure of the one or more NAND dies in response to the voltage level of the first voltage source satisfying a threshold; and
perform, during a second duration that begins after a start of the initialization procedure, a wakeup procedure to wake up the one or more controllers in response to transitioning the memory system from the idle state to the awake state.

2. The memory system of claim 1, wherein the one or more controllers are further configured to cause the memory system to:
determine whether to enable automatic triggering of the initialization procedure in accordance with a voltage level of a respective pad of one of the one or more NAND dies, wherein performing the initialization procedure is in response to determining to enable the automatic triggering of the initialization procedure after the voltage level of the respective pad satisfies a second threshold.

3. The memory system of claim 2, wherein the voltage level of the respective pad of the one or more NAND dies is in accordance with a voltage level of a second voltage source, a respective general purpose input/output (GPIO) pin of the one or more controllers, or both.

4. The memory system of claim 3, wherein the one or more controllers are further configured to cause the memory system to:
reconfigure the respective pad of the one or more NAND dies from being coupled with to the second voltage source to being coupled with a data line in response to completion of the initialization procedure at the one or more NAND dies.

5. The memory system of claim 1, wherein the one or more controllers are further configured to cause the memory system to:
receive, at the one or more NAND dies, a set of trim settings from the one or more controllers in response to a completion of the wakeup procedure.

6. The memory system of claim 1, wherein, to perform the initialization procedure of the one or more NAND dies, the one or more controllers are configured to cause the memory system to:
stagger a second plane read operation by a delay relative to performing a first plane read operation in accordance with a peak operating current of the memory system during the initialization procedure; and
perform the second plane read operation in response to expiration of the delay.

7. The memory system of claim 1, wherein the one or more controllers are further configured to cause the memory system to:
setting, during the transition of the memory system from the idle state to the awake state, voltage levels of a respective set of multi-die select (MDS) pad to each of the one or more NAND dies, wherein the voltage levels of the respective set of MDS pads indicate a respective identifier for each of the one or more NAND dies,
wherein, to perform the initialization procedure, the one or more controllers are configured to cause the memory system to:
stagger the performance of the initialization procedure between each of the one or more NAND dies according to a respective delay for each of the one or more NAND dies, wherein the respective delay for each of the one or more NAND dies is in accordance with the respective identifier of each of the one or more NAND dies.

8. The memory system of claim 7, wherein the one or more controllers are further configured to cause the memory system to:
receive, at the one or more NAND dies and in response to a completion of the initialization procedure, a respective command to reconfigure the respective identifiers for each of the one or more NAND dies to a default value.

9. The memory system of claim 1, wherein the one or more controllers are further configured to cause the memory system to:
generate, for each of the one or more NAND dies, a respective delay in accordance with respective device information associated with each of the one or more NAND dies,
wherein, to perform the initialization procedure, the one or more controllers are configured to cause the memory system to:
stagger the performance of the initialization procedure between each of the one or more NAND dies according to the respective delay of each of the one or more NAND dies.

10. The memory system of claim 9, wherein the respective device information comprises a respective position of each of the one or more NAND dies.

11. The memory system of claim 9, wherein the respective device information for each of the one or more NAND dies is stored in a respective fuse, in a respective portion of read-only memory (ROM), or both.

12. The memory system of claim 1, wherein the one or more controllers are further configured to cause the memory system to:
communicate, during the first duration and between each of the one or more NAND dies, operating currents of each of the one or more NAND dies, wherein performance of the initialization procedure at each of the one or more NAND dies is in accordance with a sum of the operating currents of each of the one or more NAND dies.

13. The memory system of claim 12, wherein the one or more controllers are further configured to cause the memory system to:
identify that a first NAND die of the one or more NAND dies is a master die according to a voltage level of a pad of the first NAND die satisfying a second threshold; and
transmit, by the first NAND die to at least a second NAND die of the one or more NAND dies, a clock signal, wherein communicating the operating currents of each of the one or more NAND dies is in accordance with the clock signal transmitted from the first NAND die.

14. The memory system of claim 1, wherein the performance of the initialization procedure is further in response to a voltage level of a second voltage source satisfying a second voltage threshold.

15. The memory system of claim 1, wherein the idle state comprises a hibernate state or an off state.

16. A non-transitory computer-readable medium storing code comprising instructions which, when executed by one or more processors of a memory system, cause the memory system to:
transition the memory system from an idle state to an awake state in accordance with a voltage level of a first voltage source, the memory system comprising one or more Not AND (NAND) dies;
perform, during a first duration, an initialization procedure of the one or more NAND dies in response to the voltage level of the first voltage source satisfying a threshold; and
perform, during a second duration that begins after a start of the initialization procedure, a wakeup procedure to wake up the one or more processors in response to transitioning the memory system from the idle state to the awake state.

17. The non-transitory computer-readable medium of claim 16, wherein the instructions, when executed by the one or more processors of the memory system, further cause the memory system to:
determine whether to enable automatic triggering of the initialization procedure in accordance with a voltage level of a respective pad of one of the one or more NAND dies, wherein performing the initialization procedure is in response to determining to enable the automatic triggering of the initialization procedure after the voltage level of the respective pad satisfies a second threshold.

18. The non-transitory computer-readable medium of claim 17, wherein the voltage level of the respective pad of the one or more NAND dies is in accordance with a voltage level of a second voltage source, a respective general purpose input/output (GPIO) pin of the one or more processors, or both.

19. The non-transitory computer-readable medium of claim 18, wherein the instructions, when executed by the one or more processors of the memory system, further cause the memory system to:
reconfigure the respective pad of the one or more NAND dies from being coupled with to the second voltage source to being coupled with a data line in response to completion of the initialization procedure at the one or more NAND dies.

20. A method, comprising:
transitioning a memory system from an idle state to an awake state in accordance with a voltage level of a first voltage source, the memory system comprising one or more controllers and one or more Not AND (NAND) dies;
performing, during a first duration, an initialization procedure of the one or more NAND dies in response to the voltage level of the first voltage source satisfying a threshold; and
performing, during a second duration that begins after a start of the initialization procedure, a wakeup procedure to wake up the one or more controllers in response to transitioning the memory system from the idle state to the awake state.
